(19) United States
(12) Patent Application Publication
(10) Pub. No.: US 2007/0117227 A1
(43) Pub. Date: May 24, 2007

(54) Method And System for Iteratively, Selectively Tuning A Parameter Of A Doped Workpiece Using A Pulsed Laser

(75) Inventor: Bo Gu, North Andover, MA (US)

Correspondence Address: BROOKS KUSHMAN P.C., 1000 TOWN CENTER, TWENTY-SECOND FLOOR, SOUTHFIELD, MI, 48075, US

(73) Assignee: GSI GROUP CORPORATION, Billerica, MA (US)

(21) Appl. No.: 11/552,180

(22) Filed: Oct. 24, 2006

Related U.S. Application Data
(60) Provisional application No. 60/739,817, filed on Nov. 23, 2005.

(51) Int. Cl. H01L 21/66; H01L 23/58; H01L 21/84

(52) U.S. Cl. 438/14; 438/151; 257/48

(57) ABSTRACT

A method and system for iteratively, selectively tuning a parameter of a doped workpiece, such as the impedance of an integrated semiconductor device, by modifying the dopant profile of a region of relatively low dopant concentration by controlled diffusion of dopants from one or more adjacent regions of relatively higher dopant concentration through melting action caused by one or more laser pulses created by a Q-switched, pulsed laser are disclosed. In particular, the method and system are directed to increasing the dopant concentration of the region of lower dopant concentration, but may also be adapted to decrease the dopant concentration of the region.

### CROSS REFERENCE TO RELATED APPLICATION

This application claims the benefit of U.S. provisional application Ser. No. 60/739,817 filed Nov. 23, 2005.

### BACKGROUND OF THE INVENTION

1. Field of the Invention

The present invention relates to the field of doped workpieces such as integrated semiconductor devices, and is directed to a method and system for iteratively, selectively tuning (i.e. modifying, changing) a parameter such as the impedance of integrated semiconductor devices using a focused pulsed laser beam. More particularly, the invention relates to a method of selectively tuning the impedance of integrated semiconductor devices, by modifying the dopant profile of a region of low dopant concentration (i.e. increasing the dopant concentration) by controlled diffusion of dopants from one or more adjacent regions of higher dopant concentration through the melting action of a focused pulsed beam provided by a pulsed laser.

2. Background Art

The use of lasers in the field of integrated semiconductor devices is known in the art, for example U.S. Pat. No. 4,636,404 to Raffle et al., U.S. Pat. No. 5,087,589 to Chapman, et al., U.S. Pat. No. 4,585,490 to Raffle et al. However, lasers in this field have mainly been used for creating links between various components, for implementing defect avoidance using redundancy in large random access memories and in complex VLSI circuits, and for restructuring or repairing circuits. For example, U.S. Pat. No. 4,636,404 uses a laser to create a conductive, low resistance bridge across a gap between laterally spaced apart metallic components in a circuit. U.S. Pat. No. 5,087,589 teaches of the creation of vertical conductive selected link regions after having performed ion implantation of the circuit.

Further, U.S. Pat. No. 5,585,490 is concerned with creating vertical links by connecting vertically spaced apart metal layers by exposing link points to a laser pulse. The use of lasers in the art in relation with integrated circuits is therefore mainly directed to the creation of conductive links and pathways where none existed before.

To accomplish the creation of conductive links between metal connectors, the prior art teaches the use of lasers capable of delivering a high intensity laser pulse. The heating action of the high-powered laser pulse cause breaks and fissures to appear in the silicon oxide (or other insulator) spacing apart the metal lines. The heating action of the laser pulse further causes some of the metal of the connectors to melt, which melted metal infiltrates into the fissures and cracks in the insulator, thus creating a link between the two connectors. The methods taught in the above patents therefore requires the application of a single, powerful laser pulse. Following the application of the since laser pulse, no further laser pulse is applied. Therefore, these patents are concerned only with the creation of low resistance links, i.e. laser diffusible links, and not with in any way accurately modifying the impedance across a given device.

Modifying the impedance or resistance of integrated semiconductor devices through the use of lasers is however known in the art. Such methods, sometimes known as laser trimming of integrated semiconductor devices is most often performed on a semiconductor device having a resistive thin film structure, manufactured with materials such as silicon cliromide, cesium silicides, tantalum nitride or nichrome. The trimming of the integrated semiconductor device, in order to achieve a required or desired resistance value is obtained by laser ablation, (i.e. by evaporation, or burning off), of a part of the resistive thin film. In other word, the laser is used to evaporate a portion of a resistive thin film structure, which due to the change in the amount of resistive thin film that remains, causes a change in the resistance value of the integrated semiconductor device.

This method comprises a number of disadvantages and limitations. One of the principal limitation of this method is that the final resistance value of the resistive thin film after the laser ablation depends on the film material itself, the quantity of material that is removed (i.e. evaporated) through laser ablation, and the pattern or shape of the ablated area. Thus if a large resistance change is required, a large area needs to be ablated, which may not be possible with the very small scale of some integrated circuits. Thus conventional laser ablation techniques generally do not allow for flexibility in any required change of resistance or impedance once the circuit has been designed and built. A further severe limitations of laser ablation technology lies in the fact that the resistive value of the trimmed device after ablation may not remain constant, and may change with time. This resulting change of the resistance value of the resistive thin film with time, which may be known as resistance drift, may be caused by a long term annealing effect of the laser ablated area. This long term annealing or “aging” effect may result from a slow decrease in the size of the thin film crystallites and may cause, with time, a significant rise of the film resistance value. This change is highly undesirable, as it may, through time, bring about a deterioration of the integrated circuit characteristics, in a field where even small variations in characteristics may not be acceptable.

A further disadvantage of laser trimming is that the ablation itself (or evaporation) of the thin film may result in damage to the surrounding integrated device. For example, residual material from the evaporation process (i.e. the material which is itself ablated or evaporated) may splatter adjacent components of the circuit, and therefore damage them. Further, the laser power output required for the resistive thin film evaporation can, in some instances, affect adjacent circuit elements by causing thermal damage, and can consequently induce unexpected and unwanted dysfunction of the integrated semiconductor device.

Further, standard manufacturing processes of integrated circuits may not include resistive thin film manufacturing steps. Therefore, additional deposition steps may be required to manufacture resistive thin film, thus increasing cost and complexity of the integrated device. Further, in some cases, a passivation layer may need to be deposited on the circuit after the laser trimming process in order to protect the resistive thin film from surrounding chemical contamination. These additional steps necessitate the use of additional manufacturing processes and therefore corresponding increased costs.

A further important disadvantage of known or conventional laser ablation techniques for trimming integrated resistors is the relatively large size of the thin film resistors themselves required in order to be able to successfully perform the ablation. In fact, due to manufacturing tolerances and other constraints, the size of the thin film may have to be much larger than the actual area which is to be ablated by laser. This wasted area surrounding the laser ablated area drastically reduces the efficiency of the architecture of the integrated circuit. Not only are unnecessary costs incurred in additional silicon, but large dimensions impose major restrictions, especially for high frequency integrated circuit elements. As miniaturization is of tremendous importance in the semiconductor industry, and as manufactures and users require ever smaller and more dense devices, laser ablation for trimming the resistance of integrated circuits becomes uneconomical, impractical, if not impossible.

Finally, a further disadvantage of known laser ablation techniques for modifying the resistance of integrated resistors is that known conventional laser trimming techniques can only increase the resistance value of the film, in other words, the technique can only work in one direction by increasing the resistance of the resistors. Known laser ablation techniques cannot lower the resistance of integrated resistors, and it therefore follows that if during the trimming procedure, over-trimming occurs and the achieved resistance is too high for the required use, there is no way of reversing this and trimming the resistance downwardly. Overtiming of a circuit may therefore cause the whole circuit to be scraped. Further, the use of lasers or other focused heat sources is unknown in the art to modify the impedance, i.e. increase or decrease the impedance of integrated semiconductor device.

U.S. Pat. No. 6,329,272 (i.e. the '272 patent), the entire contents of which are incorporated herein by reference, describes a method and apparatus for iteratively and selectively tuning the impedance of integrated semiconductor devices or components through the use of a focused heating source. It is suggested that one of the heating sources can be a modulated CW laser and the heating pulse is of duration between 1 femto-second and 1 millisecond.

U.S. Pat. No. 4,351,674, the entire contents of which are incorporated herein by reference, discloses a method of producing a semiconductor device wherein a region containing a high concentration of impurity and a desired region adjacent thereto are fused by irradiation with a laser beam, to diffuse the impurity in the lateral direction into the desired region and to render the desired region a low resistance.

### SUMMARY OF THE INVENTION

It is therefore an object of one aspect of the present invention to provide a method and system for iteratively, selectively tuning a parameter of a doped workpiece through the use of a focused pulsed laser beam.

In carrying out the above object and other objects of the present invention, a method for iteratively, selectively tuning a parameter of a doped workpiece by controllably modifying dopant profiles of adjacent regions of the workpiece is provided. The method includes the step of selectively melting, with a laser pulse generated by a pulsed laser, target material in an overlapping region of the workpiece which overlaps adjacent regions of the workpiece. One of the adjacent regions has a relatively high dopant concentration and the other of the adjacent regions has a relatively low dopant concentration to obtain molten material in the overlapping region which allows dopant to thermally diffuse in the molten material in a direction from the relatively high dopant concentration to the relatively low dopant concentration. The method also includes the step of allowing the molten material to solidify. The overlapping region has a dopant concentration lower than the relatively high dopant concentration and higher than the relatively low dopant concentration. The method still further includes repeating the above-noted steps until the value of the parameter is within a desired range of values for the parameter.

The method may further include the step of measuring a parameter of the workpiece after the molten material has solidified to obtain a measured value for the parameter. Then the step of repeating and the step of measuring are performed until the measured value of the parameter is within the desired range of values for the parameter.

The workpiece may include an integrated semiconductor device.

The parameter may include an impedance of the device.

The laser pulse may be generated by a Q-switched pulsed laser.

The laser pulse may include at least one modifiable characteristic.

The method may further include the step of modifying the modifiable characteristic after the step of measuring and before the step of melting is repeated.

The workpiece may include a diffused adjustable resistor and the parameter may be an impedance of the resistor.

The laser pulse may include a pulse width of about 50 ns and the pulsed laser may have a repetition rate greater than about 50 KHz.

Further in carrying out the above object and other objects of the present invention, a system for iteratively, selectively tuning a parameter of a doped workpiece is provided. The system includes a laser subsystem including a pulsed laser having a repetition rate and a beam delivery subsystem coupled to the pulsed laser subsystem to selectively irradiate a portion of the workpiece with a focused, pulsed laser beam having a spot size on target material of the device with a positioning accuracy. Each laser pulse has a pulse width, pulse energy, power and energy densities on the target material and a pulse shape. The system further includes a probe subsystem for measuring a parameter of the workpiece and a controller coupled to the subsystems to control the subsystems to selectively melt the target material in an overlapping region of the workpiece which overlaps adjacent regions of the workpiece. One of the adjacent regions has a relatively high dopant concentration and the other of the adjacent regions has a relatively low dopant concentration to obtain molten material in the overlapping region which allows dopant to thermally diffuse in the molten material in a direction from the relatively high dopant concentration to the relatively low dopant concentration. The controller also controls the subsystems to allow the molten material to solidify. The overlapping region has a dopant concentration lower than the relatively high dopant concentration and higher than the relatively low dopant concentration. The controller also controls the subsystems to measure a parameter of the workpiece after the molten material has solidified to obtain a measured value for the parameter. The controller controls the subsystems to repeat the above-noted steps until the measured value of the parameter is within a desired range of values for the parameter.

The pulsed laser may include a Q-switched, pulsed laser.

The pulsed laser may be a pulsed green laser.

The pulsed laser may be a milli-watt level laser.

The pulsed laser may have a wavelength in the range of 0.25 microns to 1.2 microns.

The repetition rate may be in the range of 10 KHz to 500 KHz.

The pulse energy may be in the range of 0.01 microjoules to 100 microjoules.

The spot size may be in the range of 1 micron to 10 microns in diameter.

The energy density may be in the range of 0.1 J/cm² to 1.5 J/cm².

The power density may be in the range of 10 MW/cm² to 80 MW/cm².

The beam delivery subsystem may include a beam deflector to scan a laser beam along a path which includes the target material to be melted and the positioning accuracy may be in the range of 0.1 micron to 5 microns.

The pulse width may be about 50 ns and the repetition rate may be greater than about 50 KHz.

The pulse shape may be a Gaussian waveform.

The above object and other objects, features, and advantages of the present invention are readily apparent from the following detailed description of the best mode for carrying out the invention when taken in connection with the accompanying drawings.

### BRIEF DESCRIPTION OF THE DRAWINGS

FIG. 1 is a schematic view of a laser fine-tuning system including a pulsed laser constructed in accordance with one embodiment of the present invention;

FIG. 2 is a schematic block diagram of an electronic control system of a pulsed laser fine-tuning system constructed in accordance with one embodiment of the present invention;

FIG. 3 is a schematic block diagram which illustrates the system configuration;

FIG. 4 is a schematic diagram of a conventional, laser-tunable resistor;

FIGS. 5a-5c are graphs of pulse width, pulse energy, and average power all versus frequency, for a pulsed laser useful in one embodiment of the present invention;

FIG. 6 is a graph of temperature versus depth into metal which illustrates the effect of thermal diffusion with a 10 nanosecond laser pulse;

FIG. 7 is a schematic view of a silicon substrate being hit by a laser beam and which illustrates a three dimensional effect; and

FIG. 8 is a schematic view of the substrate of FIG. 7 when the laser beam hits a region of different doping levels.

### DETAILED DESCRIPTION OF THE PREFERRED EMBODIMENT(S)

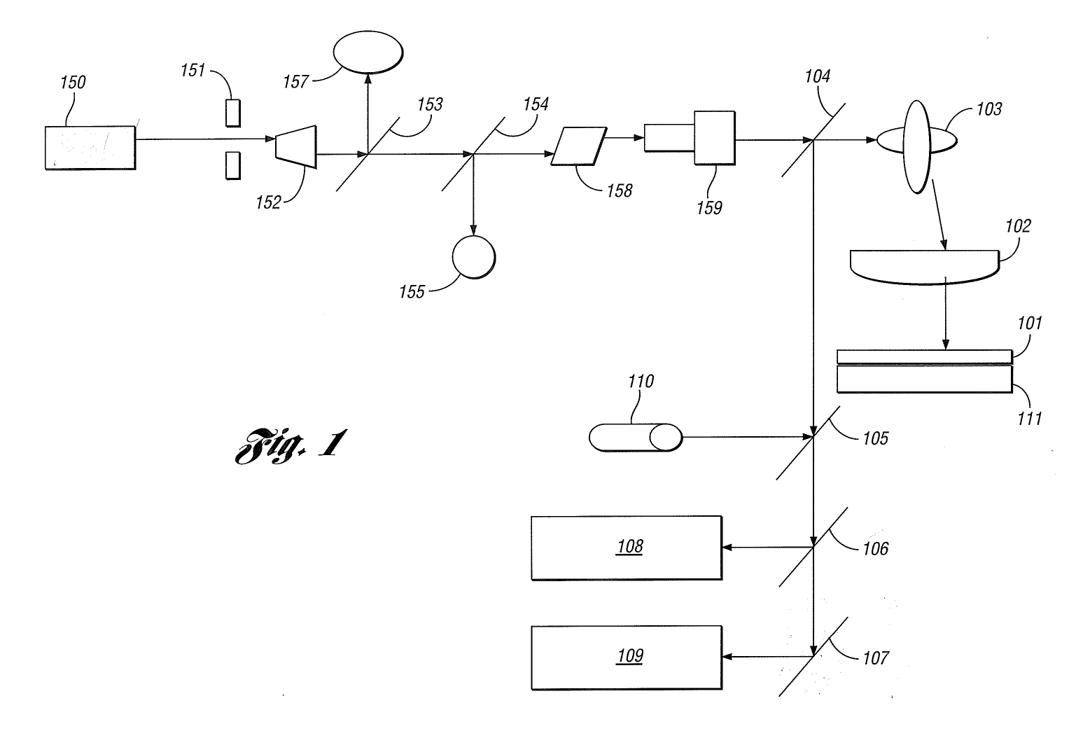

Turning to FIGS. 1, 2 and 3, there is illustrated a representation of a general embodiment of a typical laser fine tuning system and its control system for modifying the impedance of an integrated semiconductor device or workpiece 101 using a focused pulsed laser source, such as a Q-switched pulsed laser 150 (e.g., at 532 nm). The workpiece 101 is tested or probed by a probe/tester 111.

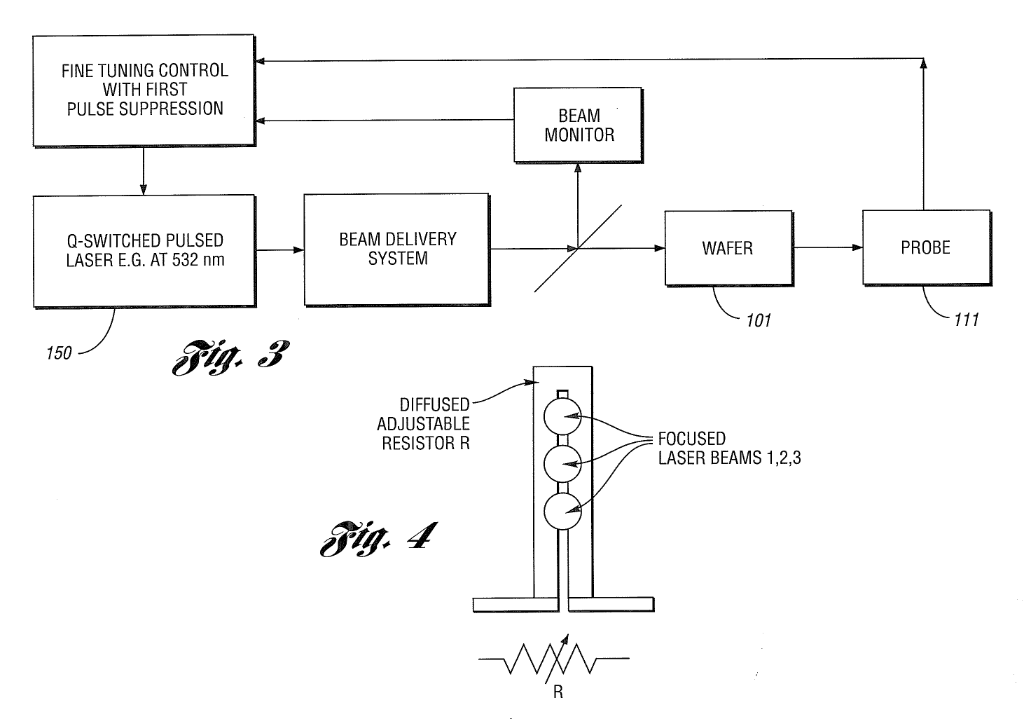

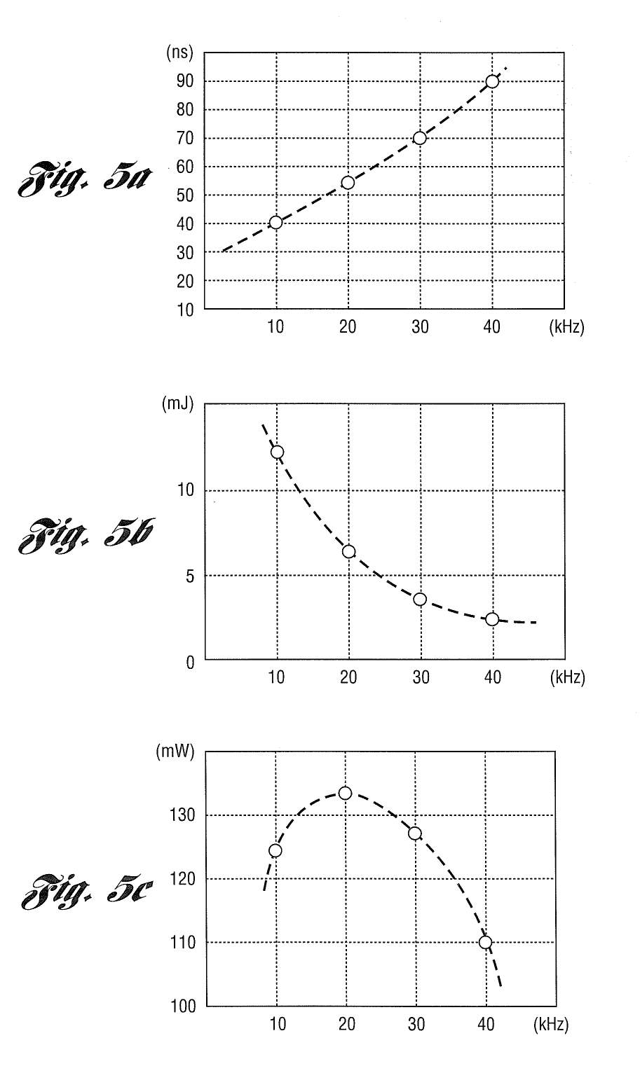

Specifically, the Q-switched pulsed laser 150 operates at green wavelength, e.g. 532 nm, for the laser fine-tuning process. This type of laser is commercially available. For example, a laser (model QG-532-100) from CrystaLaser or Reno, Nev., has characteristics shown in the graphs of FIGS. 5a-5c.

A clear advantage of using the pulsed laser 150 versus using a CW laser with modulation lies in the total average laser power needed for the process. For example, for a dose of 0.1 μj with 20-ns pulse duration, it requires a 5-watt CW laser. For the same dose at 50 KHz, it requires only a 5-mw pulsed laser, a reduction of 1,000 times in average power. A milli-watt level laser can easily be air-cooled while a multi-watt laser may have to be water-cooled. The footprint of a milli-watt level laser is also much smaller than that of a multi-watt laser.

The pulsed laser 150 also gives better results in open-loop trimming tests, i.e., better repeatability (tighter resistance value distribution). For example, for one part, TSMC025UM, the following final target values were achieved with distribution:

| | |
|---|---|
| CW Green Laser with Modulation | 360 Ohm +/− 215 Ohm |
| Pulsed Green Laser | 398 Ohm +/− 74 Ohm |

Clearly, the pulsed laser 150 gives a tighter tolerance. This difference might be attributed to the temporal profile difference between a modulated CW laser source (a square waveform) and a Q-switched pulsed laser (a Gaussian waveform).

System Configuration

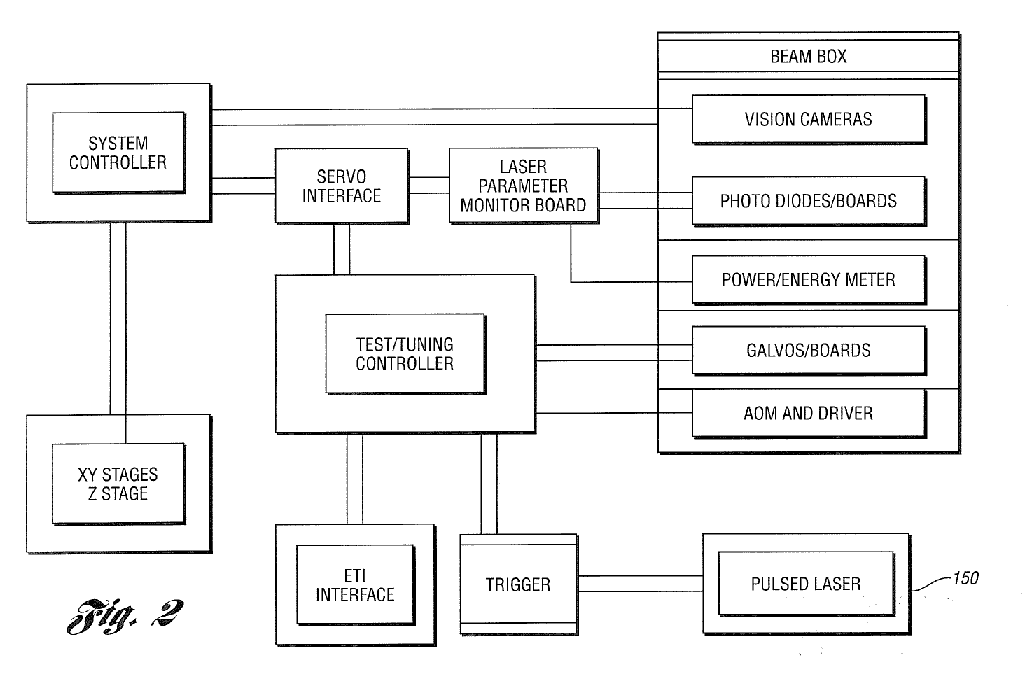

A typical laser fine-tuning system based on the Q-switched laser 150 is illustrated in FIG. 1. A block diagram of an electronic control system of a typical pulsed laser fine-tuning system is given in FIG. 2. FIG. 3 illustrates the system configuration.

A typical laser-tunable resistor is shown in FIG. 4.

Contributing to the fine-tuning process are at least the following parameters: the laser beam spot size, laser beam profile, the location of the laser beam on the resistor area (and its accuracy), the number of the laser pulses, the laser pulse energy, and the laser pulse width and the laser pulse shape (temporal profile).

Laser Process Parameters

The Q-switched pulsed laser 150 preferably has a wavelength of 532 nm. Other wavelengths can also be used as long as there is enough absorption of the laser energy by the semiconductor material. Therefore, the range can be from 1.2 μm down to 0.25 μm. The repetition rates are from 10 KHz to 500 KHz. Pulse energy ranges from 0.01 μj to 100 μj. The spot size on the target ranges from 10 μm in diameter down to 1 μm with beam positioning accuracy from 5 μm to 0.1 μm. The energy density on the target ranges from 0.1 J/cm² to 1.5 J/cm². The power density ranges from 10 MW/cm² to 80 MW/cm².

A typical processing condition is as follows:

A laser spot size on the target is around 4 μm in diameter. Laser pulse width is 50 ns and repetition rate 100 KHz. Pulse energy on the target is 0.1 μj. The energy density is around 0.7 J/cm² and power density around 14 MW/cm². The positioning accuracy is +/−1 μm with the galvanometer-based system of FIG. 1.

The integrated circuit or workpiece 101 is placed on a positioning table or X-Y stage, and is subjected to an application of a focused laser pulse, which is produced by the laser 150. Laser pulses are focused on the integrated circuit 101 by using: a machining head or objective lens 102 for 532 nm; X and Y galvo scanners for 532 nm; a dichroic mirror (532 nm/880 nm) 104; a Z-galvo scanner 158; a telescope beam expander 159; beam splitters 153 and 154; a laser eye photodiode 155; a PAPC 157; and a laser power/energy attenuator such as an AOM or other attenuator mechanism 152.

A system of cameras and mirrors allows for the observation of the integrated circuit 101 in order to ensure accurate alignment of the focused laser pulses. The system further comprises low and high magnification vision cameras 108 and 109, respectively, and a light source or illuminator 110 (e.g. 880 nm). Further components of the system include a beam splitter 105, a turning mirror 107, and a beam splitter 106.

The laser 150 is connected to a laser safety shutter 151, each of which is controlled by a controller of a control system shown in FIG. 5. Also connected to the controller are X-Y stages and a Z stage.

Heat Affected Zone (HAZ) is a Three Dimensional Effect

When a laser pulse hits the material, the electrons absorb the laser energy very quickly (less than pico seconds). The energy will then be transferred to the surrounding area via electron-lattice interaction, generally called “thermal diffusion. ”

This diffusion effect is three dimensional, i.e., the energy will transfer in all directions (not only in the lateral x and y plane, but in the z direction as well). The dimension z of the thermal diffusion can be estimated by the square root of the product of pulse width, tₚ, and material diffusivity, D.

The curve of FIG. 6 illustrates the effect of thermal diffusion with a 10 nano-second laser pulse interacting with copper and aluminum (they both have similar thermal diffusivity).

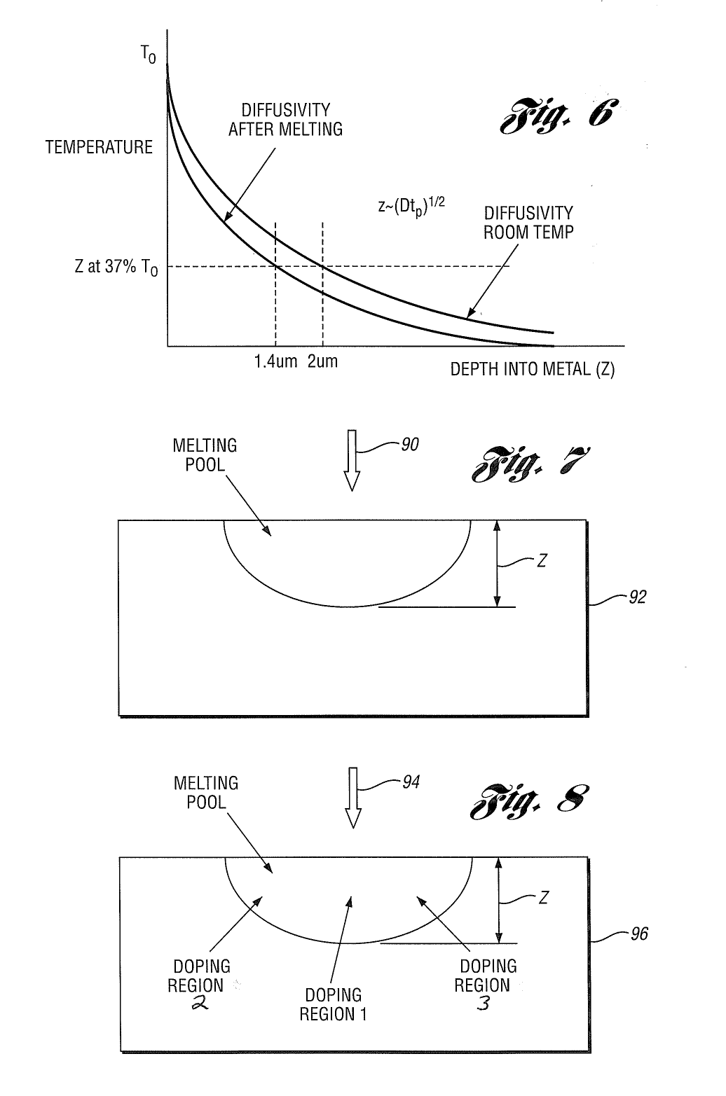

FIG. 7 shows the three dimensional effect when a laser beam 90 having pulse width, tₚ, hits a silicon substrate 92. The melting region, caused by the thermal effect, is of three dimensions, as indicated in the figure.

FIG. 8 shows that when a laser beam 94 having a pulse width, tₚ, hits a region of a silicon substrate 96 consisting of three different doping level regions, the doping level and profile of the regions will change.

The substrates 92 and 96 can alternatively have a layered structure.

The iterative process of a particular embodiment of the present invention has progressively dropped the resistance across the integrated semiconductor device, through the application of a number of laser pulses from a focused pulsed laser source, wherein the characteristics of the laser pulse were modified, as required in order to effect a progressively closer result to the final desired result.

In order to obtain integrated semiconductor devices with the required precise impedance characteristics, a very precise control of dopant diffusion into a lightly doped region may be necessary. For example, if an integrated semiconductor device of low or very low impedance (i.e. resistance) is required, the controlled diffusion in accordance with an embodiment of the present invention may require a significant amount of dopants to diffuse into the lightly doped region from heavily doped regions. The end result in accordance with this embodiment may be, for example, to create a quasi-uniform dopants distribution from a heavily doped region, across a formerly lightly doped region and through a heavily doped region. In such a situation, voltage/current curve of the tuned integrated semiconductor device may show excellent linearity.

Alternatively, applications may call for a high impedance (i.e. resistance) device, which may be obtained by controlled diffusion of a small or minimum amount of dopant into a lightly doped region from heavily doped regions. As a result, in accordance with this embodiment, there may be a non-uniform distribution of dopant in the lightly doped region between heavily doped regions. It is known that non-uniform doping in semiconductor devices creates non-linear phenomena. In such a situation, voltage/current curve of the tuned integrated semiconductor device may show strong non-linear characteristics.

To solve this problem and to obtain high impedance devices, conventional serial integrated resistors may be added which may limit voltage on tunable part of the integrated semiconductor device and may make it work in the linear region noted above.

The integrated semiconductor device may further comprise serial resistors. This has the effect of creating a linear current-voltage curve of the apparatus.

Summary of One Embodiment of the Invention

In at least one embodiment of the present invention, a method of iteratively, selectively and accurately tuning the impedance of an integrated semiconductor device by controlled diffusion of dopants from a first region having a first dopant concentration to an immediately adjacent second region having a lower dopant concentration than the first region is provided. The method includes: directing a focused pulsed laser source to a selected area which straddles a portion of each of said first region and said second region, and applying a laser pulse from said focused pulsed laser source thereto. The laser pulse melts the selected area thereby allowing the controlled diffusion of dopants from the first region to the second region. The method also includes allowing the melted selected areas to solidify. The solidified selected area now is a third region having a dopant concentration which is intermediate the dopant concentration of the first region and the second region. The method further includes measuring the impedance of said semiconductor device to determine if the impedance is either higher than required, or lower than required. If the impedance is higher than required, then the method includes directing the focused pulsed laser source to a portion of the first region adjacent to the third region and applying a laser pulse thereto. The laser pulse melts the portion of the first region and further melts the adjacent third region thereby allowing for the controlled diffusion of additional dopants from the melted portion of the first region to the melted third region. The method includes allowing the melted areas to solidify. If the impedance is lower than required, then the method includes directing the focused pulsed laser source to a portion of the second region adjacent to the third region and applying a laser pulse thereto. The laser pulse melts the portion of the second region and further melts the adjacent third region thereby allowing for the controlled diffusion of dopants from the third region to the melted portion of the second region. The method then includes allowing the melted areas to solidify, and repeating the iterative steps until the desired impedance of the integrated semiconductor device is achieved.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A method for iteratively, selectively tuning a parameter of a doped workpiece by controllably modifying dopant profiles of adjacent regions of the workpiece, the method comprising:
a) selectively melting, with a laser pulse generated by a pulsed laser, target material in an overlapping region of the workpiece which overlaps adjacent regions of the workpiece, one of the adjacent regions having a relatively high dopant concentration and the other of the adjacent regions having a relatively low dopant concentration to obtain molten material in the overlapping region which allows dopant to thermally diffuse in the molten material in a direction from the relatively high dopant concentration to the relatively low dopant concentration;
b) allowing the molten material to solidify wherein the overlapping region has a dopant concentration lower than the relatively high dopant concentration and higher than the relatively low dopant concentration; and
c) repeating steps a) and b) until the value of the parameter is within a desired range of values for the parameter.

2. The method as claimed in claim 1 further comprising measuring the parameter of the workpiece after step b) to obtain a measured value for the parameter and wherein steps a) and b) and the step of measuring are repeated until the measured value of the parameter is within the desired range of values for the parameter.

3. The method as claimed in claim 1, wherein the workpiece is an integrated semiconductor device.

4. The method as claimed in claim 1, wherein the parameter is impedance of the device.

5. The method as claimed in claim 1, wherein the laser pulse is generated by a Q-switched pulsed laser.

6. The method as claimed in claim 1, wherein the laser pulse has at least one modifiable characteristic.

7. The method as claimed in claim 6 further comprising the step of modifying the modifiable characteristic before steps a) and b) are repeated.

8. The method as claimed in claim 1, wherein the workpiece is a diffused adjustable resistor and the parameter is impedance of the resistor.

9. The method as claimed in claim 1, wherein the laser pulse has a pulse width of about 50 ns and the pulsed laser has a repetition rate greater than about 50 KHz.

10. A system for iteratively, selectively tuning a parameter of a doped workpiece, the system comprising:
a laser subsystem including a pulsed laser having a repetition rate;
a beam delivery subsystem coupled to the pulsed laser subsystem to selectively irradiate a portion of the workpiece with a focused, pulsed laser beam having a spot size on target material of the device with a positioning accuracy, each laser pulse having a pulse width, pulse energy, power and energy densities on the target material and a pulse shape;
a probe subsystem for measuring a parameter of the workpiece; and
a controller coupled to the subsystems to control the subsystems to:
a) selectively melt the target material in an overlapping region of the workpiece which overlaps adjacent regions of the workpiece, one of the adjacent regions having a relatively high dopant concentration and the other of the adjacent regions having a relatively low dopant concentration to obtain molten material in the overlapping region which allows dopant to thermally diffuse in the molten material in a direction from the relatively high dopant concentration to the relatively low dopant concentration;
b) allow the molten material to solidify wherein the overlapping region has a dopant concentration lower than the relatively high dopant concentration and higher than the relatively low dopant concentration;
c) measure a parameter of the workpiece after the molten material has solidified to obtain a measured value for the parameter; and
d) repeat steps a), b) and c) until the measured value of the parameter is within a desired range of values for the parameter.

11. The system as claimed in claim 10, wherein the pulsed laser is a Q-switched, pulsed laser.

12. The system as claimed in claim 10, wherein the pulsed laser is a pulsed green laser.

13. The system as claimed in claim 10, wherein the pulsed laser is a milli-watt level laser.

14. The system as claimed in claim 10, wherein the pulsed laser has a wavelength in the range of 0.25 microns to 1.2 microns.

15. The system as claimed in claim 10, wherein the repetition rate is in the range of 10 KHz to 500 KHz.

16. The system as claimed in claim 10, wherein the pulse energy is in the range of 0.01 microjoules to 100 microjoules.

17. The system as claimed in claim 10, wherein the spot size is in the range of 1 micron to 10 microns in diameter.

18. The system as claimed in claim 10, wherein the energy density is in the range of 0.1 J/cm² to 1.5 J/cm².

19. The system as claimed in claim 10, wherein the power density is in the range of 10 MW/cm² to 80 MW/cm².

20. The system as claimed in claim 10, wherein the beam delivery subsystem includes a beam deflector to scan a laser beam along a path which includes the target material to be melted and wherein the positioning accuracy is in the range of 0.1 micron to 5 microns.

21. The system as claimed in claim 10, wherein the pulse width is about 50 ns and the repetition rate is greater than about 50 KHz.

22. The system as claimed in claim 10, wherein the pulse shape is a Gaussian waveform.
